(19) United States
(12) Patent Application Publication
(10) Pub. No.: US 2025/0057030 A1
(43) Pub. Date: Feb. 13, 2025

(54) DISPLAY DEVICE HAVING A BENDING DISPLAY PANEL

(71) Applicant: SAMSUNG DISPLAY CO., LTD., YONGIN-SI (KR)

(72) Inventors: DAEHO KIM, YONGIN-SI (KR); SANGBONG LEE, YONGIN-SI (KR); HOICK CHO, YONGIN-SI (KR)

(21) Appl. No.: 18/650,249

(22) Filed: Apr. 30, 2024

(30) Foreign Application Priority Data
Aug. 10, 2023 (KR) 10-2023-0105119

(51) Int. Cl. H10K 77/10; H10K 59/38; H10K 59/40; H10K 59/80; H10K 102/00

(52) U.S. Cl. CPC H10K 77/111; H10K 59/38; H10K 59/40; H10K 59/8722; H10K 59/8794; H10K 2102/311

(57) ABSTRACT

A display device includes a display panel including a first non-bending portion, a bending portion, and a second non-bending portion. A flexible circuit board includes a first flexible circuit board disposed on an upper surface of the second non-bending portion and a second flexible circuit board disposed on a lower surface of the second non-bending portion. A lower support is disposed under the first non-bending portion. An adhesive tape is disposed on a lower surface of the lower support and a lower surface of the second flexible circuit board when the bending portion is bent. The adhesive tape disposed on the lower surface of the second flexible circuit board is disposed at an edge of the second flexible circuit board.

This U.S. non-provisional patent application claims priority under 35 U.S.C. § 119 to Korean Patent Application No. 10-2023-0105119, filed on Aug. 10, 2023, the contents of which are hereby incorporated by reference in its entirety.

### TECHNICAL FIELD

The present disclosure relates to a display device and, more specifically, to a display device having a bending display panel.

### DISCUSSION OF THE RELATED ART

Various display devices are widely used in multimedia devices, such as televisions, mobile phones, tablet computers, and portable video game console devices. The display devices include various optical elements to provide images with excellent quality to a user. Researches on various optical elements are being conducted to increase an image display quality and an image display efficiency in various display devices.

### SUMMARY

A display device includes a display panel including a first non-bending portion, a bending portion, and a second non-bending portion. A flexible circuit board includes a first flexible circuit board disposed on an upper surface of the second non-bending portion and a second flexible circuit board disposed on a lower surface of the second non-bending portion. A lower support is disposed under the first non-bending portion, and an adhesive tape is disposed on a lower surface of the lower support and a lower surface of the second flexible circuit board. The adhesive tape disposed on the lower surface of the second flexible circuit board is disposed at an edge of the second flexible circuit board.

A display device includes a display panel including a first non-bending portion, a bending portion, and a second non-bending portion. A lower support is disposed under the display panel. The lower support includes a lower adhesive layer including a plurality of protruding patterns disposed on a surface thereof facing the display panel, a cushion layer disposed under the lower adhesive layer, and a heat dissipation layer disposed under the cushion layer and including stainless steel. The cushion layer is nonporous.

### BRIEF DESCRIPTION OF THE DRAWINGS

The above and other aspects of the present disclosure will become readily apparent by reference to the following detailed description when considered in conjunction with the accompanying drawings wherein:

FIG. 1 is a perspective view of a display device according to an embodiment of the present disclosure;

FIG. 2 is an exploded perspective view of the display device shown in FIG. 1;

FIG. 3 is a cross-sectional view of a display module shown in FIG. 2;

FIG. 4 is a cross-sectional view of a display module according to an embodiment of the present disclosure;

FIG. 5 is a cross-sectional view of a display device according to an embodiment of the present disclosure;

FIG. 6 is a cross-sectional view of a display device according to an embodiment of the present disclosure;

FIG. 7 is a cross-sectional view of a display device according to a comparative example;

FIG. 8A is a cross-sectional view illustrating a lower support shown in FIG. 2;

FIG. 8B is a cross-sectional view illustrating a lower support according to an embodiment of the present disclosure;

FIG. 9 is a cross-sectional view of a display device according to an embodiment of the present disclosure;

FIG. 10 is a cross-sectional view of a lower support according to a comparative example;

FIGS. 11A and 11B are cross-sectional views illustrating a display module and

a lower support shown in FIG. 2;

FIG. 12 is a perspective view of a display device according to an embodiment of the present disclosure;

FIGS. 13A and 13B are cross-sectional views illustrating display devices according to embodiments of the present disclosure; and

FIGS. 14A and 14B are images illustrating display devices according to a comparative example and an embodiment example of the present disclosure.

### DETAILED DESCRIPTION

Features of the inventive concept and methods of accomplishing the same may be understood more readily by reference to the following detailed description of embodiments and the accompanying drawings. The inventive concept may, however, be embodied in many different forms and should not necessarily be construed as being limited to the embodiments set forth herein. Rather, these embodiments are provided so that this disclosure will be through and complete and will fully convey the inventive concept to those skilled in the art. Like reference numerals may denote like elements throughout the specification and the drawings.

In the present disclosure, it will be understood that when an element or layer is referred to as being “on”, “connected to” or “coupled to” another element or layer, it can be directly on, connected or coupled to the other element or layer or intervening elements or layers may be present. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms first, second, etc. may be used herein to describe various elements, components, regions, layers and/or sections, these elements, components, regions, layers and/or sections should not necessarily be limited by these terms. These terms are used to distinguish one element, component, region, layer or section from another region, layer or section. Thus, a first element, component, region, layer or section discussed below could be termed a second element, component, region, layer or section without departing from the teachings of the present disclosure.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, embodiments of the present disclosure will be described with reference to accompanying drawings.

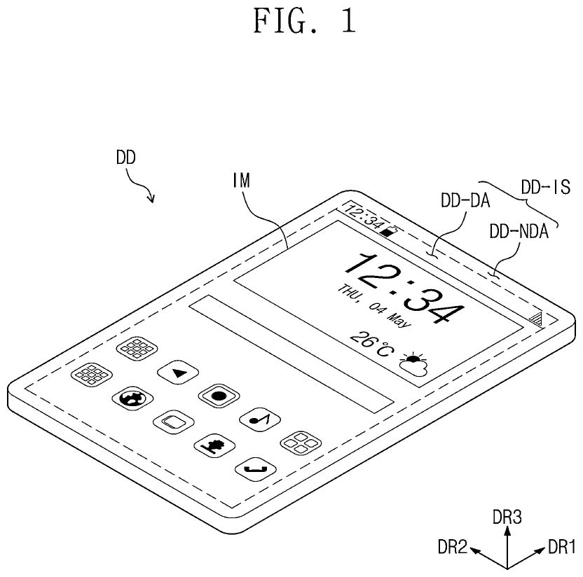

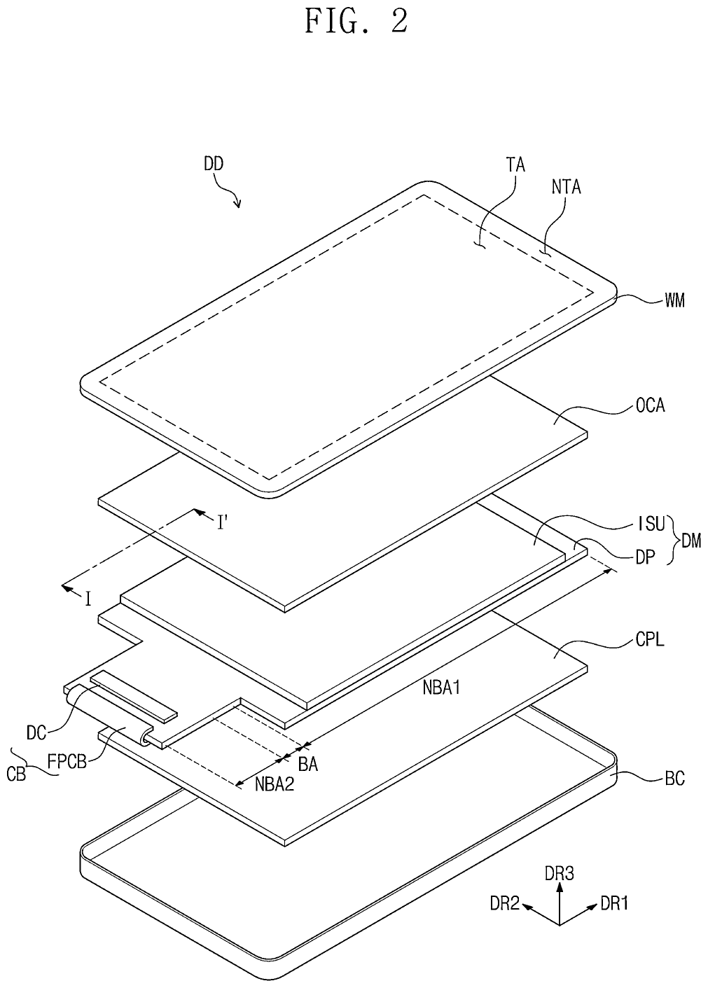

FIG. 1 is a perspective view of a display device DD according to an embodiment of the present disclosure. FIG. 2 is an exploded perspective view of the display device DD shown in FIG. 1.

Referring to FIG. 1, a mobile phone terminal is shown as the display device DD as a representative example. The display device DD, according to the present disclosure, may be applied to a large-sized electronic item, such as a television set and a computer monitor, and a small and medium-sized electronic item, such as a tablet computer, a car navigation unit, a portable game unit, and a smart watch.

The display device DD may have a rectangular shape defined by a pair of long sides extending in a first direction DR1 and a pair of short sides extending in a second direction DR2 intersecting the first direction DR1. However, the shape of the display device DD should not necessarily be limited to the rectangular shape, and the display device DD may have various shapes, such as a circular shape and a polygonal shape.

Hereinafter, a direction substantially perpendicular to a plane defined by the first direction DR1 and the second direction DR2 may be referred to as a third direction DR3. In the present disclosure, the expression “when viewed in a plane” or “in a plan view” may mean a state of being viewed in the third direction DR3.

The display device DD of the present disclosure may be rigid or flexible. The term “flexible” used herein refers to the property of being able to be bent from a structure that is completely bent to a structure that is bent at the scale of a few nanometers. For example, the flexible display device DD may be a curved electronic device, a rollable electronic device, or a foldable electronic device.

The display device DD may display an image IM through a display surface DD-IS. Icon images are shown as a representative example of the image IM. The display surface DD-IS may be substantially parallel to the plane defined by the first direction DR1 and the second direction DR2.

The display surface DD-IS may include a display area DD-DA through which the image IM is displayed and a non-display area DD-NDA defined adjacent to the display area DD-DA and at least partially surrounding the display area DD-DA. The image IM might not be displayed through the non-display area DD-NDA. According to an embodiment, the non-display area DD-NDA may be omitted or may be defined adjacent to only one side of the display area DD-DA.

Referring to FIG. 2, the display device DD may include a window WM, an upper adhesive layer OCA, a display module DM, a lower support CPL, and an accommodation member BC such as a bottom casing.

The window WM may be disposed on the display module DM and may transmit an image provided from the display module DM to the outside thereof. The window WM may include a transmission area TA and a non-transmission area NTA. The transmission area TA may overlap the display area DD-DA shown in FIG. 1 and may have a shape corresponding to that of the display area DD-DA. The window WM may include a base layer and functional layers disposed on the base layer. The functional layers may include a protective layer, an anti-fingerprint layer, etc.

The base layer of the window WM may include a glass, sapphire, or plastic. The base layer of the window WM may include an optically transparent insulating material. As an example, the base layer of the window WM may include a glass or plastic film or may include a glass substrate and a plastic film coupled to the glass substrate by an adhesive.

The non-transmission area NTA may overlap the non-display area DD-NDA shown in FIG. 1 and may have a shape corresponding to that of the non-display area DD-NDA. The non-transmission area NTA may have a relatively low light transmittance as compared with that of the transmission area TA. A bezel pattern may be disposed in an area of the base layer of the window WM, the area in which the bezel pattern is disposed may be defined as the non-transmission area NTA, and an area of the base layer in which the bezel pattern is not disposed may be defined as the transmission area TA. However, the present disclosure should not necessarily be limited thereto or thereby, and the non-transmission area NTA may be omitted.

The display module DM may be disposed under the window WM. The display module DM may include a display panel DP and an input sensor ISU.

The display panel DP may be one of a liquid crystal display panel, an electrophoretic display panel, a microelectromechanical system (MEMS) display panel, an electrowetting display panel, an organic light emitting display panel, an inorganic light emitting display panel, and a quantum dot light emitting display panel, and it should not particularly limited thereto. Hereinafter, the organic light emitting display panel will be described as the display panel DP.

The input sensor ISU may include one of a capacitive sensor, an optical sensor, an ultrasonic sensor, and an electromagnetic induction sensor. The input sensor ISU may be formed on the display panel DP through successive processes or may be attached to an upper portion of the display panel DP using an adhesive layer, after being separately manufactured.

The display module DM may include a circuit board CB. The circuit board CB may include a driving chip DC and a flexible circuit board FPCB. FIG. 2 shows a structure in which the driving chip DC is mounted on the display panel DP, however, the present disclosure should not necessarily be limited thereto or thereby. The driving chip DC may generate a driving signal required to operate the display panel DP in response to a control signal provided from the flexible circuit board FPCB.

The display panel DP may include a bending portion BA, a first non-bending portion NBA1, and a second non-bending portion NBA2. The first non-bending portion NBA1 and the second non-bending portion NBA2 may be spaced apart from each other with the bending portion BA interposed therebetween in the first direction DR1.

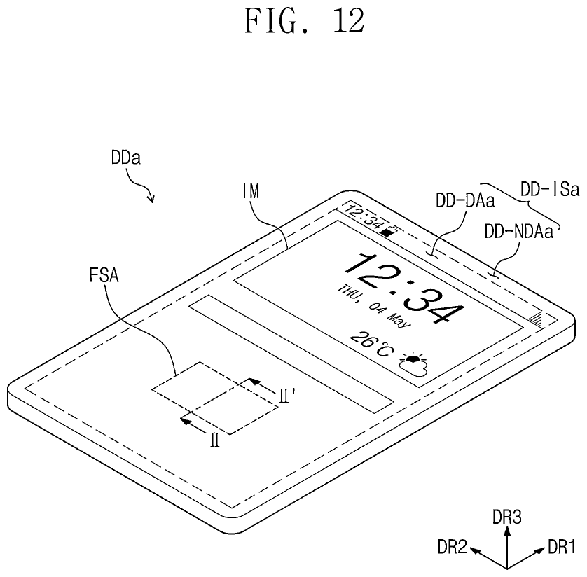

The bending portion BA may be a portion of the display panel DP, which is bent with respect to an imaginary bending axis extending in the second direction DR2. The first non-bending portion NBA1 may overlap the transmission area TA, and the second non-bending portion NBA2 may be defined as an area to which the flexible circuit board FPCB is connected. When the bending portion BA is bent with respect to the bending axis, the flexible circuit board FPCB and the driving chip DC may be bent toward a rear surface of the display panel DP and may be disposed under the display panel DP. The bending of the bending portion BA will be described in detail with reference to FIGS. 11A and 11B. Additional components may be provided to the display device DD to compensate for a step difference caused by the bending portion BA between the circuit board CB and the rear surface of the display panel DP.

According to an embodiment, a width in the second direction DR2 of the first non-bending portion NBA1 may be greater than a width in the second direction DR2 of the bending portion BA and the second non-bending portion NBA2, however, the present disclosure should not necessarily be limited thereto or thereby. According to an embodiment, the width in the second direction DR2 of the bending portion BA may gradually decrease from the first non-bending portion NBA1 to the second non-bending portion NBA2, however, it should not necessarily be limited thereto or thereby.

The flexible circuit board FPCB may be disposed at one end of the display panel DP. The flexible circuit board FPCB may be disposed on an upper surface of the second non-bending portion NBA2. A portion of the flexible circuit board FPCB may be disposed on the upper surface of the second non-bending portion NBA2, and another portion of the flexible circuit board FPCB may be bent to be disposed under the second non-bending portion NBA2. This will be described in detail with reference to FIGS. 11A and 11B.

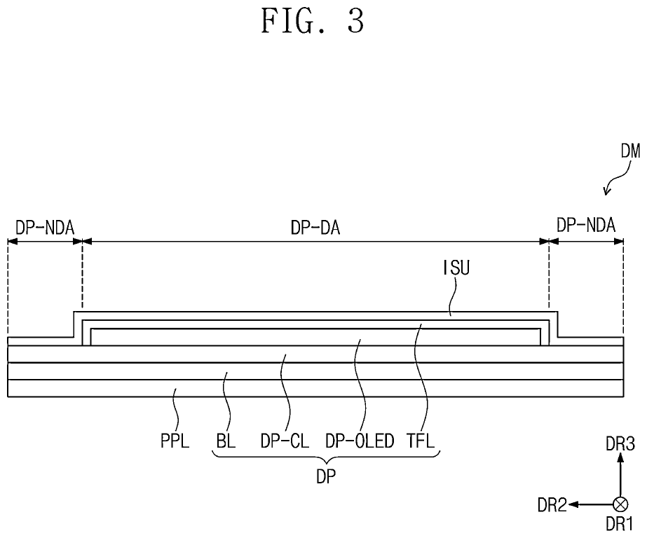

The flexible circuit board FPCB may be connected to the display panel DP. The flexible circuit board FPCB may be electrically connected to a circuit element layer DP-CL described with reference to FIG. 3.

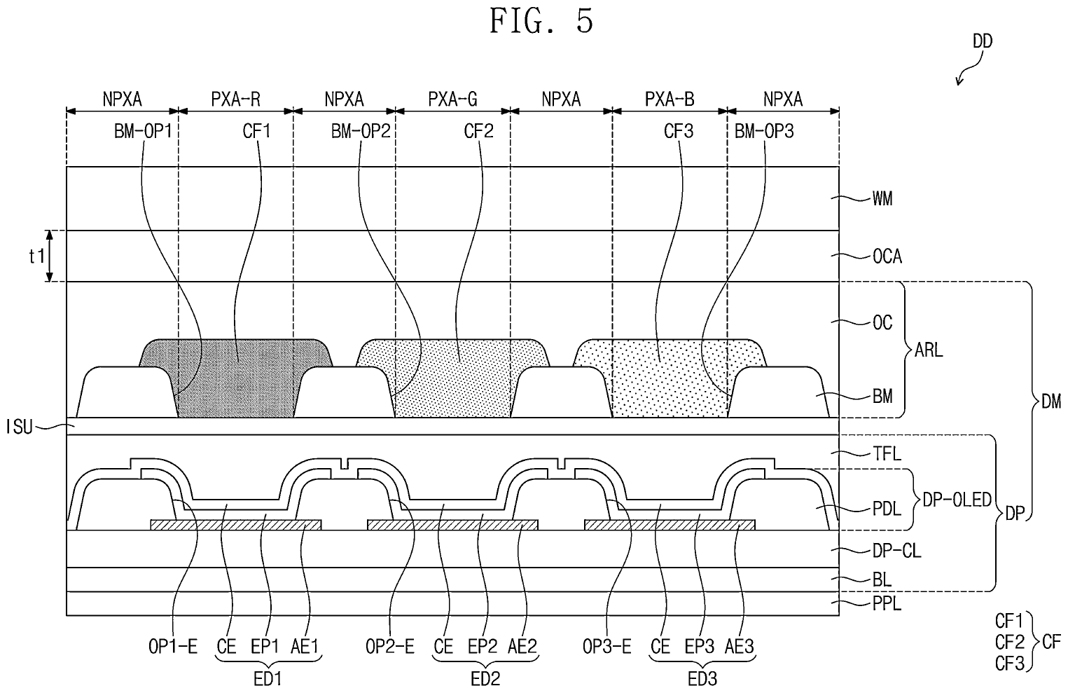

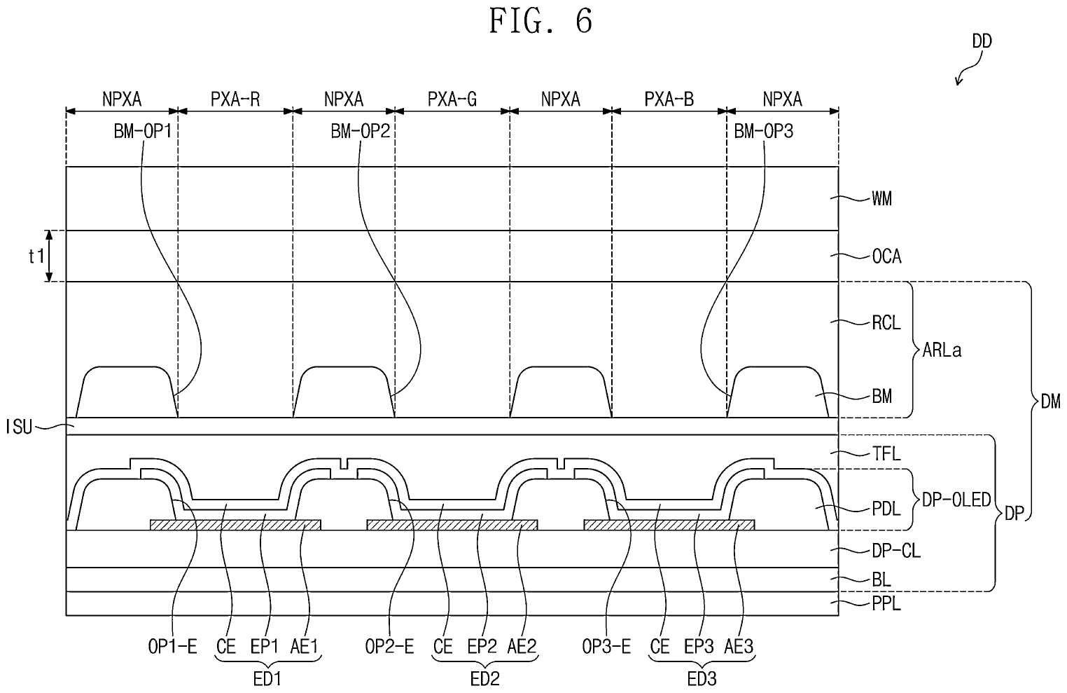

The display module DM may further include an anti-reflective layer. The anti-reflective layer may reduce a reflectance of an external light incident thereto from the outside of the display device DD. The anti-reflective layer will be described in detail with reference to FIGS. 5 and 6.

The upper adhesive layer OCA may be disposed between the window WM and the display module DM. The upper adhesive layer OCA may be disposed on the first non-bending portion NBA1. The upper adhesive layer OCA may have a rectangular shape defined by a pair of long sides extending in the first direction DR1 and a pair of short sides extending in the second direction DR2. The window WM and the display module DM may be attached to each other by the upper adhesive layer OCA.

The accommodation member BC may be disposed under the display module DM. The accommodation member BC may accommodate the display module DM, the upper adhesive layer OCA, and the lower support CPL described below and may be coupled with the window WM.

The lower support CPL may be disposed between the display module DM and the accommodation member BC. The lower support CPL may be disposed under the first non-bending portion NBA1. The lower support CPL may have a rectangular shape defined by a pair of long sides extending in the first direction DR1 and a pair of short sides extending in the second direction DR2.

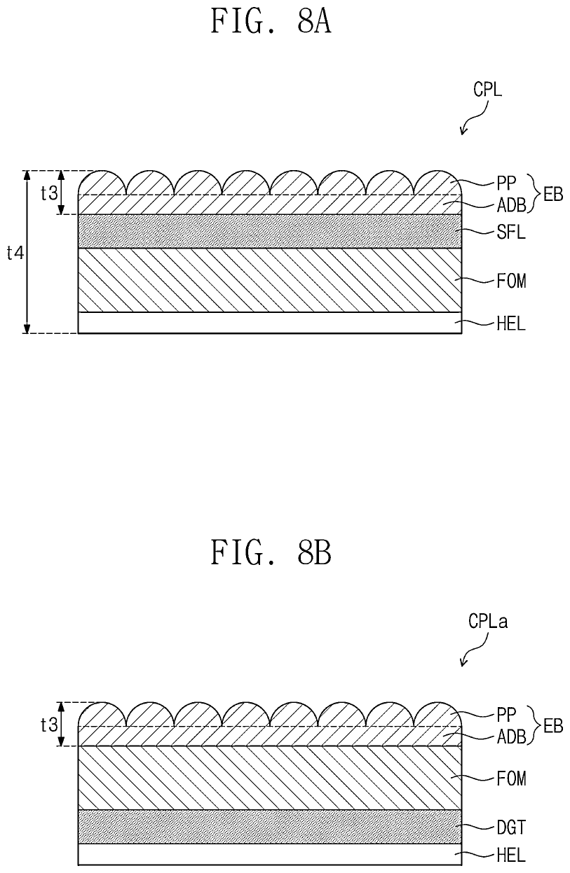

The lower support CPL may include a cushion layer, a heat dissipation layer, etc. The lower support CPL will be described in detail with reference to FIGS. 8A and 8B.

FIG. 3 is a cross-sectional view of the display module DM shown in FIG. 2.

Referring to FIG. 3, the display module DM may include the input sensor ISU, the display panel DP, and a panel protective layer PPL. The display panel DP may include a base layer BL, the circuit element layer DP-CL, a display element layer DP-OLED, and an upper insulating layer TFL, which are sequentially stacked on the base layer BL. The input sensor ISU may be disposed on the upper insulating layer TFL.

The display panel DP may include a display area DP-DA and a non-display area DP-NDA. The display area DP-DA of the display panel DP may correspond to the display area DD-DA shown in FIG. 1 or the transmission area TA shown in FIG. 2, and the non-display area DP-NDA may correspond to the non-display area DD-NDA shown in FIG. 1 or the non-transmission area NTA shown in FIG. 2.

The base layer BL may include at least one plastic film. The base layer BL may be a flexible substrate and may include a plastic substrate, a glass substrate, a metal substrate, or an organic/inorganic composite material substrate.

The circuit element layer DP-CL may include at least one intermediate insulating layer and a circuit element. The intermediate insulating layer may include at least one intermediate inorganic layer and at least one intermediate organic layer. The circuit element may include signal lines and a pixel driving circuit.

The display element layer DP-OLED may include a plurality of organic light emitting diodes. The display element layer DP-OLED may further include an organic layer such as a pixel definition layer.

The upper insulating layer TFL may encapsulate the display element layer DP-OLED. The upper insulating layer TFL may be disposed on the display element layer DP-OLED. The upper insulating layer TFL may overlap the display area DP-DA and the non-display area DP-NDA. The upper insulating layer TFL may overlap at least a portion of the non-display area DP-NDA. As an example, the upper insulating layer TFL may include a thin film encapsulation layer. The thin film encapsulation layer may have a stack structure of an inorganic layer/organic layer/inorganic layer. The upper insulating layer TFL may protect the display element layer DP-OLED from moisture, oxygen, and a foreign substance such as dust particles, however, it should not necessarily be limited thereto or thereby. According to an embodiment, the upper insulating layer TFL may further include an additional insulating layer in addition to the thin film encapsulation layer. Hereinafter, the upper insulating layer TFL will be described as a thin film encapsulation layer TFL.

According to an embodiment, a sealing substrate may be provided instead of the upper insulating layer TFL. In this case, the sealing substrate may face the base layer BL, and the circuit element layer DP-CL and the display element layer DP-OLED may be disposed between the sealing substrate and the base layer BL.

The input sensor ISU may be disposed directly on the display panel DP. In the present disclosure, the expression “component A is disposed directly on component B” means that no intervening elements are present between the component A and the component B. In the present embodiment, the input sensor ISU may be formed through successive processes with the display panel DP, however, the present disclosure should not necessarily be limited thereto or thereby. According to an embodiment, the input sensor ISU may be provided as an individual panel and then may be coupled to the display panel DP by an adhesive layer. According to an embodiment, the input sensor ISU may be omitted.

The panel protective layer PPL may be disposed under the display panel DP. The panel protective layer PPL may protect a lower portion of the display panel DP. The panel protective layer PPL may include a flexible plastic material. As an example, the panel protective layer PPL may include polyethylene terephthalate (PET).

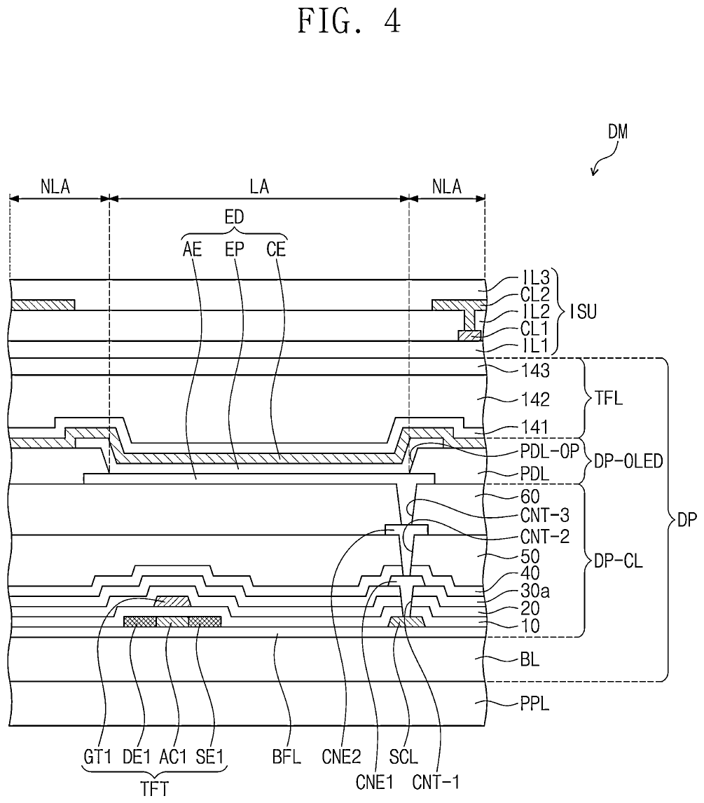

FIG. 4 is a cross-sectional view of the display module DM according to an embodiment of the present disclosure.

FIG. 4 shows a cross-section corresponding to one light emitting area LA and a non-light-emitting area NLA at least partially surrounding the one light emitting area LA. FIG. 4 shows only one light emitting area LA, however, the light emitting area LA may be provided in plural.

FIG. 4 shows a light emitting element ED and one transistor TFT connected to the light emitting element ED as an example. However, the light emitting element ED may be connected to a plurality of transistors and at least one capacitor.

As an example, the transistor TFT of FIG. 4 will be described as a silicon transistor, however, according to an embodiment, the transistor TFT may be a metal oxide transistor.

Referring to FIG. 4, the display module DM may include the input sensor ISU, the display panel DP, and the panel protective panel PPL. The display panel DP may include the base layer BL, the circuit element layer DP-CL, the display element layer DP-OLED, and the thin film encapsulation layer TFL.

The base layer BL may provide a base surface on which the circuit element layer DP-CL is disposed. The base layer BL may be a rigid substrate or a flexible substrate that is bendable, foldable, or rollable. The base layer BL may be a plastic substrate, a glass substrate, a metal substrate, or an organic/inorganic composite material substrate.

The base layer BL may have a multi-layer structure. For example, the base layer BL may include a first synthetic resin layer, an inorganic layer having a single-layer or multi-layer structure, and a second synthetic resin layer disposed on the inorganic layer having a single-layer or multi-layer structure. Each of the first and second synthetic resin layers may include a polyimide-based resin, however, it should not necessarily be particularly limited thereto.

The circuit element layer DP-CL may be disposed on the base layer BL. The circuit element layer DP-CL may include an insulating layer, a semiconductor pattern, a conductive pattern, a signal line, and a pixel driving circuit. The circuit element layer DP-CL may include a buffer layer BFL, first, second, third, fourth, fifth, and sixth insulating layers 10, 20, 30, 40, 50, and 60, a signal transmission area SCL, and plural connection electrodes CNE1 and CNE2.

The buffer layer BFL may be disposed on the base layer BL. The buffer layer BFL may prevent metal atoms or impurities from being diffused to the semiconductor pattern disposed thereon from the base layer BL. A rear surface metal layer may be further disposed between the base layer BL and the buffer layer BFL. The rear surface metal layer may be disposed under the transistor TFT described later and may prevent the external light from reaching the transistor TFT.

The semiconductor pattern may be disposed on the buffer layer BFL. The semiconductor pattern may include a silicon semiconductor. As an example, the silicon semiconductor may include amorphous silicon or polycrystalline silicon. For example, the semiconductor pattern may include low temperature polycrystalline silicon.

The semiconductor pattern may include a first region having a relatively high conductivity and a second region having a relatively low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration that is lower than that of the first region.

The first region may have a conductivity that is greater than that of the second region and may substantially serve as an electrode or a signal line. The second region may substantially correspond to an active area (or a channel) of the transistor. For example, a portion of the semiconductor pattern may be the active area of the transistor, another portion of the semiconductor pattern may be a source or a drain of the transistor, and the other portion of the semiconductor pattern may be a connection electrode or a connection signal line.

The transistor TFT may include a source area SE1 (or a source), an active area AC1 (or a channel), a drain area DE1 (or a drain), and a gate GT1. The source area SE1, the active area AC1, and the drain area DE1 of the transistor TFT may be formed from the semiconductor pattern. The source area SE1 and the drain area DE1 may extend in opposite directions to each other from the active area AC1 in a cross-section. FIG. 4 shows a portion of the signal transmission area SCL formed from the semiconductor pattern. The signal transmission area SCL may be connected to the drain DE1 of the transistor TFT, in a plan view.

The first insulating layer 10 may be disposed on the buffer layer BFL. The first insulating layer 10 may cover the source SE1, the active area AC1, and the drain DE1 of the transistor TFT and the signal transmission area SCL, which are disposed on the buffer layer BFL.

The first insulating layer 10 may include an inorganic layer and/or an organic layer and may have a single-layer or multi-layer structure. The inorganic layer may include aluminum oxide, titanium oxide, silicon oxide, silicon nitride, silicon oxynitride, zirconium oxide, and/or hafnium oxide. In the present embodiment, the first insulating layer 10 may have a single-layer structure of a silicon oxide layer. Not only the first insulating layer 10, but also an insulating layer of the circuit element layer DP-CL described later may be an inorganic layer and/or an organic layer and may have a single-layer or multi-layer structure. The inorganic layer may include at least one of the above-mentioned materials, however, it should not necessarily be limited thereto or thereby.

The gate GT1 of the transistor TFT may be disposed on the first insulating layer 10. The gate GT1 may be a portion of a metal pattern. The gate GT1 may overlap the active area AC1. The gate GT1 may be used as a mask in a process of doping the semiconductor pattern. The gate GT1 may include titanium (Ti), silver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), indium tin oxide (ITO), indium zinc oxide (IZO), or the like, however, it should not necessarily be particularly limited thereto.

The second insulating layer 20 may be disposed on the first insulating layer 10 and may cover the gate GT1. The third insulating layer 30 may be disposed on the second insulating layer 20.

A first connection electrode CNE1 may be disposed on the third insulating layer 30. The first connection electrode CNE1 may be connected to the signal transmission area SCL via a contact hole CNT-1 defined through the first, second, and third insulating layers 10, 20, and 30. The fourth insulating layer 40 may be disposed on the third insulating layer 30 and may cover the first connection electrode CNE1. The fourth insulating layer 40 may be an organic layer.

The fifth insulating layer 50 may be disposed on the fourth insulating layer 40. A second connection electrode CNE2 may be disposed on the fifth insulating layer 50. The second connection electrode CNE2 may be connected to the first connection electrode CNE1 via a contact hole CNT-2 defined through the fourth insulating layer 40 and the fifth insulating layer 50. The fifth insulating layer 50 may be an organic layer.

The sixth insulating layer 60 may be disposed on the fifth insulating layer 50 and may cover the second connection electrode CNE2. The sixth insulating layer 60 may be an organic layer. The stack structure of the first insulating layer 10 to the sixth insulating layer 60 is merely an example, and additional conductive layer and insulating layer may be disposed in addition to the first insulating layer 10 to the sixth insulating layer 60.

The display element layer DP-OLED may be disposed on the circuit element layer DP-CL. The display element layer DP-OLED may include the light emitting element ED and the pixel definition layer PDL.

The light emitting element ED may be an organic light emitting element, an inorganic light emitting element, an organic-inorganic light emitting element, a quantum dot light emitting element, a micro-LED, or a nano-LED. However, the light emitting element ED should not necessarily be limited thereto or thereby and may include various embodiments as long as the light emitting element ED may emit a light in response to electrical signals or may control an amount of the light.

The light emitting element ED may include a first electrode AE (or an anode), a light emitting pattern EP, and a second electrode CE (or a cathode). The first electrode AE may be disposed on the sixth insulating layer 60. The first electrode AE may be a transmissive electrode, a semi-transmissive electrode, or a reflective electrode. The first electrode AE may include a reflective layer formed of Ag, Mg, Al, Pt, Pd, Au, Ni, Nd, Ir, Cr, or compounds thereof and a transparent or semi-transparent electrode layer formed on the reflective layer. The transparent or semi-transparent electrode layer may include indium tin oxide (ITO), indium zinc oxide (IZO), indium gallium zinc oxide (IGZO), zinc oxide (ZnO), indium oxide (In₂O₃), and/or aluminum-doped zinc oxide (AZO). For example, the first electrode AE may have a stack structure of ITO/Ag/ITO.

The pixel definition layer PDL may be disposed on the sixth insulating layer 60. The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal, such as carbon black, chromium, or an oxide thereof. The pixel definition layer PDL may correspond to a light blocking pattern having a light blocking property.

The pixel definition layer PDL may cover a portion of the first electrode AE. As an example, an opening PDL-OP may be defined through the pixel definition layer PDL to expose the portion of the first electrode AE. The opening PDL-OP of the pixel definition layer PDL may define the light emitting area LA.

A hole control layer may be further disposed between the first electrode AE and the light emitting pattern EP. The hole control layer may further include a hole transport layer and/or a hole injection layer. An electron control layer may be further disposed between the light emitting pattern EP and the second electrode CE. The electron control layer may further include an electron transport layer and/or an electron injection layer.

The display element layer DP-OLED may further include a capping layer. The capping layer may be disposed on the light emitting element ED and may cover the second electrode CE of the light emitting element ED. The capping layer may include an organic material. The capping layer may have a single-layer or multi-layer structure. The capping layer may sufficiently protect the cathode disposed thereunder and an organic light emitting layer disposed thereunder from moisture or contaminants from the outside, and thus, a lifespan of the light emitting element ED may be increased.

The thin film encapsulation layer TFL may be disposed on the display element layer DP-OLED. The thin film encapsulation layer TFL may protect the display element layer DP-OLED from moisture, oxygen, and a foreign substance such as dust particles. The thin film encapsulation layer TFL may include a first inorganic layer 141, an organic layer 142, and a second inorganic layer 143, which are sequentially stacked, however, layers forming the thin film encapsulation layer TFL should not necessarily be limited thereto or thereby.

The first and second inorganic layers 141 and 143 may protect the display element layer DP-OLED from moisture and oxygen, and the organic layer 142 may protect the display element layer DP-OLED from a foreign substance such as dust particles. The first and second inorganic layers 141 and 143 may include a silicon nitride layer, a silicon oxynitride layer, a silicon oxide layer, a titanium oxide layer, or an aluminum oxide layer. The organic layer 142 may include an acrylic-based organic layer, however, it should not necessarily be particularly limited thereto.

The input sensor ISU may be disposed on the display panel DP. The input sensor ISU may be referred to as a sensor layer, an input sensing layer, or an input sensing panel. The input sensor ISU may include a base insulating layer IL1, a first conductive layer CL1, a sensing insulating layer IL2, a second conductive layer CL2, and a cover layer IL3.

The base insulating layer IL1 may be disposed directly on the display panel DP. The base insulating layer IL1 may be an inorganic layer including silicon nitride, silicon oxynitride, and/or silicon oxide. According to an embodiment, the base insulating layer IL1 may be an organic layer including an epoxy resin, an acrylic resin, or an imide-based resin. The base insulating layer IL1 may have a single-layer structure or a multi-layer structure of layers stacked in the third direction DR3.

Each of the first conductive layer CL1 and the second conductive layer CL2 may have a single-layer structure or a multi-layer structure of layers stacked in the third direction DR3. Each of the first conductive layer CL1 and the second conductive layer CL2 may include a sensing pattern, which has a mesh structure, or a bridge pattern when viewed in a plane.

The conductive layer having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), indium zinc tin oxide (IZTO), or the like. In addition, the transparent conductive layer may include conductive polymer such as PEDOT, metal nanowire, graphene, or the like.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensing insulating layer IL2 may be disposed between the first conductive layer CL1 and the second conductive layer CL2. The cover layer IL3 may be disposed on the sensing insulating layer IL2 and may cover the second conductive layer CL2. The cover layer IL3 may reduce or remove a probability of damage to the second conductive layer CL2 in subsequent processes. According to an embodiment, the input sensor ISU might not include the cover layer IL3.

The sensing insulating layer IL2 and the cover layer IL3 may include an inorganic layer. The inorganic layer may include aluminum oxide, titanium oxide, silicon oxide, silicon nitride, silicon oxynitride, zirconium oxide, and/or hafnium oxide.

According to an embodiment, the sensing insulating layer IL2 and the cover layer IL3 may include an organic layer. The organic layer may include an epoxy-based resin, a urethane-based resin, a cellulose-based resin, a siloxane-based resin, a polyimide-based resin, a polyamide-based resin, and/or a perylene-based resin.

The panel protective layer PPL may be disposed under the display panel DP. The panel protective layer PPL may be disposed on a lower surface of the base layer BL. The panel protective layer PPL may include the flexible plastic material. As an example, the panel protective layer PPL may include polyethylene terephthalate (PET). The panel protective layer PPL may protect the lower portion of the display panel DP.

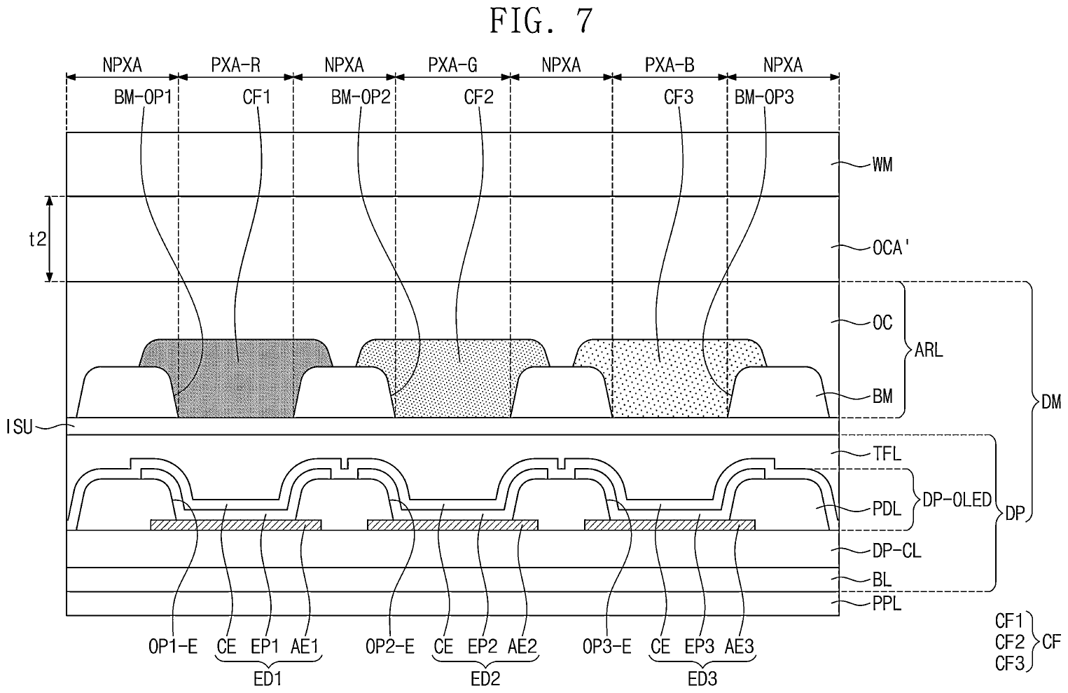

FIG. 5 is a cross-sectional view of the display device DD according to an embodiment of the present disclosure. FIG. 6 is a cross-sectional view of a display device DD according to an embodiment of the present disclosure. FIG. 7 is a cross-sectional view of a display device according to a comparative example.

For the convenience of explanation, each of a base layer BL, a circuit element layer DP-DL, and a thin film encapsulation layer TFL is schematically shown as a single layer in FIGS. 5, 6, and 7.

For the convenience of explanation, the lower support CPL shown in FIG. 2 is omitted in FIGS. 5, 6, and 7.

Since a panel protective layer PPL, the base layer BL, the circuit element layer DP-CL, a display element layer DP-OLED, and an input sensor ISU shown in FIGS. 5, 6, and 7 are substantially the same as the panel protective layer PPL, the base layer BL, the circuit element layer DP-CL, the display element layer DP-OLED, and the input sensor ISU shown in FIG. 4. To the extent that an element is not described in detail with respect to this figure, it may be understood that the element is at least similar to a corresponding element that has been described elsewhere within the present disclosure.

Descriptions about first, second, and third light emitting elements ED1, ED2, and ED3 shown in FIGS. 5 and 6 may be substantially the same as the descriptions about the light emitting element ED shown in FIG. 4.

Since a display module DM and an anti-reflective layer ARL of FIG. 7 are substantially the same as a display module DM and an anti-reflective layer ARL of FIG. 5, descriptions hereinafter will be focused on different features of the display module DM and the anti-reflective layer ARL.

Referring to FIGS. 4, 5, and 6, the display panel DP may include the first, second, and third light emitting elements ED1, ED2, and ED3. The first light emitting element ED1 may include a first anode AE1, a first light emitting pattern EP1, and a portion of the cathode CE. The second light emitting element ED2 may include a second anode AE2, a second light emitting pattern EP2, and a portion of the cathode CE. The third light emitting element ED3 may include a third anode AE3, a third light emitting pattern EP3, and a portion of the cathode CE.

The first, second, and third anodes AE1, AE2, and AE3 may be provided as a plurality of patterns. First, second, and third light emitting openings OP1-E, OP2-E, and OP3-E may be defined through the pixel definition layer PDL. At least a portion of the first anode AE1 may be exposed through the first light emitting opening OP1-E. At least a portion of the second anode AE2 may be exposed through the second light emitting opening OP2-E. At least a portion of the third anode AE3 may be exposed through the third light emitting opening OP3-E.

The first, second, and third light emitting patterns EP1, EP2, and EP3 may be disposed on the first, second, and third anodes AE1, AE2, and AE3, respectively, and may be disposed on the pixel definition layer PDL. The first, second, and third light emitting patterns EP1, EP2, and EP3 may be disposed in the first, second, and third light emitting openings OP1-E, OP2-E, and OP3-E, respectively. The first light emitting pattern EP1 may be disposed in the first light emitting opening OP1-E, the second light emitting pattern EP2 may be disposed in the second light emitting opening OP2-E, and the third light emitting pattern EP3 may be disposed in the third light emitting opening OP3-E. The cathode CE may be disposed on the first, second, and third light emitting patterns EP1, EP2, and EP3 and the pixel definition layer PDL.

FIGS. 4 to 6 show a structure in which the first, second, and third light emitting patterns EP1, EP2, and EP3 are respectively disposed on the first, second, and third anodes AE1, AE2, and AE3 and may be disposed on the pixel definition layer PDL as a representative example, however, the present disclosure should not necessarily be limited thereto or thereby. As an example, the first, second, and third light emitting patterns EP1, EP2, and EP3 may be disposed only on the first, second, and third anodes AE1, AE2, and AE3, respectively.

The first, second, and third light emitting patterns EP1, EP2, and EP3 may emit light having different colors from each other. As an example, the first light emitting pattern EP1 may provide a red light, the second light emitting pattern EP2 may provide a green light, and the third light emitting pattern EP3 may provide a blue light.

Referring to FIG. 5, the display module DM may further include the anti-reflective layer ARL. The anti-reflective layer ARL may reduce the reflectance of the external light. The anti-reflective layer ARL may include a light shielding pattern BM, a color filter CF, and an overcoating layer OC.

The light shielding pattern BM may be disposed on the input sensor ISU. The light shielding pattern BM may have a black color and may include a black coloring agent. The black coloring agent may include a black pigment or a black dye. The black coloring agent may include a metal, such as carbon black, chromium, or an oxide thereof. However, this is merely an example, and the material for the light shielding pattern BM should not necessarily be particularly limited thereto as long as the material absorbs the light.

The light shielding pattern BM may prevent the external light from being reflected by the first conductive layer CL1 and the second conductive layer CL2. The light shielding pattern BM may overlap the pixel definition layer PDL. First, second, and third openings BM-OP1, BM-OP2, and BM-OP3 may be defined through the light shielding pattern BM. The first, second, and third openings BM-OP1, BM-OP2, and BM-OP3 of the light shielding pattern BM may overlap the first, second, and third light emitting openings OP1-E, OP2-E, and OP3-E of the pixel definition layer PDL, respectively. The first opening BM-OP1 may overlap the first light emitting opening OP1-E, the second opening BM-OP2 may overlap the second light emitting openings OP2-E, and the third opening BM-OP3 may overlap the third light emitting openings OP3-E.

The first, second, and third openings BM-OP1, BM-OP2, and BM-OP3 of the light shielding pattern BM may define first, second, and third pixel areas PXA-R, PXA-G, and PXA-B, respectively. The first, second, and third pixel areas PXA-R, PXA-G, and PXA-B may be defined as areas from which the light generated by the first, second, and third light emitting elements ED1, ED2, and ED3 are emitted to the outside, respectively.

The color filter CF may be disposed on the input sensor ISU. The color filter CF may be disposed in the first, second, and third openings BM-OP1, BM-OP2, and BM-OP3 defined by the light shielding pattern BM. A portion of the color filter CF may be disposed on the light shielding pattern BM.

The color filter CF may include a first color filter CF1, a second color filter CF2, and a third color filter CF3. Each of the first color filter CF1, the second color filter CF2, and the third color filter CF3 may overlap a corresponding pixel area among the first, second, and third pixel areas PXA-R, PXA-G, and PXA-B. A portion of each of the first color filter CF1, the second color filter CF2, and the third color filter CF3 may overlap a non-pixel area NPXA. The first color filter CF1, the second color filter CF2, and the third color filter CF3 may be disposed on the light shielding pattern BM.

Each of the first color filter CF1, the second color filter CF2, and the third color filter CF3 may overlap a corresponding light emitting element among the first, second, and third light emitting elements ED1, ED2, and ED3. The color filter CF may correspond to the first, second, and third light emitting elements ED1, ED2, and ED3 and may transmit light generated by the first, second, and third light emitting elements ED1, ED2, and ED3.

For example, the first color filter CF1 may transmit a first light provided from the first light emitting element ED1, the second color filter CF2 may transmit a second light provided from the second light emitting element ED2, and the third color filter CF3 may transmit a third light provided from the third light emitting element ED3. As an example, the first light may be a red light, the second light may be a green light, and the third light may be a blue light.

The color filter CF may block some wavelengths of the external light. For example, the first, second, and third color filters CF1, CF2, and CF3 may reduce the reflection of the external light, which is caused by the first, second, and third anodes AE1, AE2, and AE3 or the cathode CE.

Each of the first color filter CF1, the second color filter CF2, and the third color filter CF3 may include a polymer photosensitive resin and a pigment or a dye. The first color filter CF1 may include a red pigment or a red dye, the second color filter CF2 may include a green pigment or a green dye, and the third color filter CF3 may include a blue pigment or a blue dye, however, the present disclosure should not necessarily be limited thereto or thereby. According to an embodiment, the third color filter CF3 might not include the pigment and the dye. As an example, the third color filter CF3 may be formed of a transparent photosensitive resin, and the third color filter CF3 may be transparent. In the case where the third color filter CF3 is formed of the transparent photosensitive resin, the light transmitting through the third color filter CF3 should not necessarily be limited to the third light.

The overcoating layer OC may cover the light shielding pattern BM, the first color filter CF1, the second color filter CF2, and the third color filter CF3. The overcoating layer OC may include an organic material and may provide a flat upper surface thereon.

Referring to FIG. 6, an anti-reflective layer ARLa might not include the color filter CF (refer to FIG. 5). For example, the anti-reflective layer ARLa may include light shielding patterns BM and a light control layer RCL. The light control layer RCL may be filled in between light shielding patterns BM spaced apart from each other.

A dye and a pigment included in the light control layer RCL may be a material that transmits a light in a specific wavelength range among the light emitted from the light emitting elements ED1, ED2, and ED3. According to an embodiment, the dye and the pigment may absorb a light in a wavelength range equal to or greater than about 490 nm and equal to or smaller than about 505 nm and a light in a wavelength range equal to or greater than about 585 nm and equal to or smaller than about 600 nm and may transmit a light in a remaining wavelength range. As the dye and the pigment included in the light control layer RCL absorbs the light having a specific wavelength and transmits the light having other wavelength ranges, the external light may be prevented from being reflected, and thus, the color of the light emitted from the display panel DP may be controlled.

The dye and the pigment included in the light control layer RCL may include an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, and/or a cyanine-based compound. As an example, the light control layer RCL may include one of the tetraazaporphyrin-based compound, the cyanine-based compound, the squarylium-based compound, and the oxazine-based compound, or a combination thereof. The light control layer RCL may include about 0.01 wt % or more and about 5.00 wt % or less of the dye and the pigment with respect to a total content of the light control layer RCL. In a case where the light control layer RCL includes less than about 0.01 wt % of the dye and the pigment, the light in the specific wavelength range might not be sufficiently absorbed, and thus, a color reproducibility might not be increased. In a case where the light control layer RCL includes more than about 5.00 wt % of the dye and the pigment, a cohesion may occur in the dye and the pigment.

Referring to FIGS. 5 and 6, a window WM may be disposed on the anti-reflective layers ARL and ARLa. The window WM may have an optically transparent property. The window WM may include a glass, however, the present disclosure should not necessarily be limited thereto or thereby. The window WM may include a synthetic resin film.

The window WM may have a single-layer or multi-layer structure. As an example, the window WM may include a plurality of synthetic resin films coupled with each other by an adhesive or may include a glass substrate and a synthetic resin film coupled with the glass substrate by an adhesive. According to an embodiment, when the window WM includes the synthetic resin films, an upper adhesive layer OCA may be omitted.

The upper adhesive layer OCA may be disposed between the display module DM and the window WM. The display module DM and the window WM may be coupled with each other by the upper adhesive layer OCA.

The upper adhesive layer OCA may be an optically clear adhesive. The upper adhesive layer OCA may be optically transparent.

The upper adhesive layer OCA may have a thickness t1 within a range from about 75 micrometers to about 100 micrometers. The thickness t1 of the upper adhesive layer OCA may be referred to as a first thickness t1. The upper adhesive layer OCA may have an elastic modulus within a range from about 0.36 megapascals to about 0.44 megapascals.

Referring to FIGS. 5, 6, and 7, a first upper adhesive layer OCA′ shown in FIG. 7 may have a thickness t2 within a range from about 140 micrometers to about 160 micrometers. The thickness t2 of the first upper adhesive layer OCA′ may be referred to as a second thickness. The first upper adhesive layer OCA′ shown in FIG. 7 may have an elastic modulus of about 0.23 megapascals.

As the elastic modulus of the upper adhesive layer OCA is greater than the elastic modulus of the first upper adhesive layer OCA′, a repulsive force of the upper adhesive layer OCA may increase against an external force applied from the above of the display device DD. Accordingly, the upper adhesive layer OCA may be less likely to be deformed by the external force, and thus, a possibility that the upper adhesive layer OCA is visible to a user may decrease.

In addition, since the first thickness t1 of the upper adhesive layer OCA is smaller than the second thickness t2 of the first upper adhesive layer OCA′, an amount of the deformation may be small even though the external force is applied to the display device DD. For example, when the external force with the same intensity is applied to the upper adhesive layer OCA and the first upper adhesive layer OCA′, a strain rate of the upper adhesive layer OCA, which has a relatively large elastic modulus, may be smaller than a strain rate of the first upper adhesive layer OCA′. The strain rate may be defined as a ratio between the deformation in thickness and an original thickness. For example, the deformation amount may be proportional to the strain rate and the original thickness. Since the strain rate of the upper adhesive layer OCA is smaller than the strain rate of the first upper adhesive layer OCA′ and the first thickness of the upper adhesive layer OCA is smaller than the second thickness of the first upper adhesive layer OCA′, the deformation amount of the upper adhesive layer OCA may be smaller than the deformation amount of the first upper adhesive layer OCA′. Accordingly, a possibility that the deformation of the upper adhesive layer OCA is visible to a user may be reduced.

FIG. 8A is a view illustrating a lower support CPL shown in FIG. 2. FIG. 8B is a view illustrating a lower support CPLa according to an embodiment of the present disclosure.

As an example, FIGS. 8A and 8B show cross-sectional views of the lower supports CPL and CPLa.

A lower adhesive layer EB, a cushion layer FOM, and a heat dissipation layer HEL of FIG. 8B are substantially the same as a lower adhesive layer EB, a cushion layer FOM, and a heat dissipation layer HEL of FIG. 8A, and thus, to the extent that an element is not described in detail with respect to this figure, it may be understood that the element is at least similar to a corresponding element that has been described elsewhere within the present disclosure.

Referring to FIG. 8A, the lower support CPL may include the lower adhesive layer EB, a reinforcement film SFL, the cushion layer FOM, and the heat dissipation layer HEL. The lower adhesive layer EB may be disposed on the lower support CPL, and the lower support CPL may be attached to the display panel DP (refer to FIG. 6) by the lower adhesive layer EB. Materials for the lower adhesive layer EB should not necessarily be particularly limited thereto, and adhesive materials well known to those skilled in the art may be used for the lower adhesive layer EB. As an example, various polymer resins may be used as the materials for the lower adhesive layer EB. The lower adhesive layer EB may include, for example, a pressure sensitive adhesive (PSA).

The lower adhesive layer EB may include an adhesive base ADB and a protruding pattern PP. The adhesive base ADB may include an upper surface and a lower surface opposite to the upper surface, and the protruding pattern PP may be defined on the upper surface of the adhesive base ADB. The upper surface of the adhesive base ADB may be adjacent to the display panel DP (refer to FIG. 6), and the lower surface of the adhesive base ADB may face the heat dissipation layer HEL.

The protruding pattern PP may be disposed on the upper surface of the adhesive base ADB and may be defined as an embossment pattern protruded upward from the adhesive base ADB. The protruding pattern PP may be formed integrally with the adhesive base ADB.

The protruding pattern PP may have a convex upward shape. The protruding pattern PP may have a semi-circular shape in a cross-sectional view, however, the shape of the protruding pattern PP should not necessarily be limited thereto or thereby. According to an embodiment, the protruding pattern PP may have a quadrilateral shape, a semi-oval shape, or a polygonal shape.

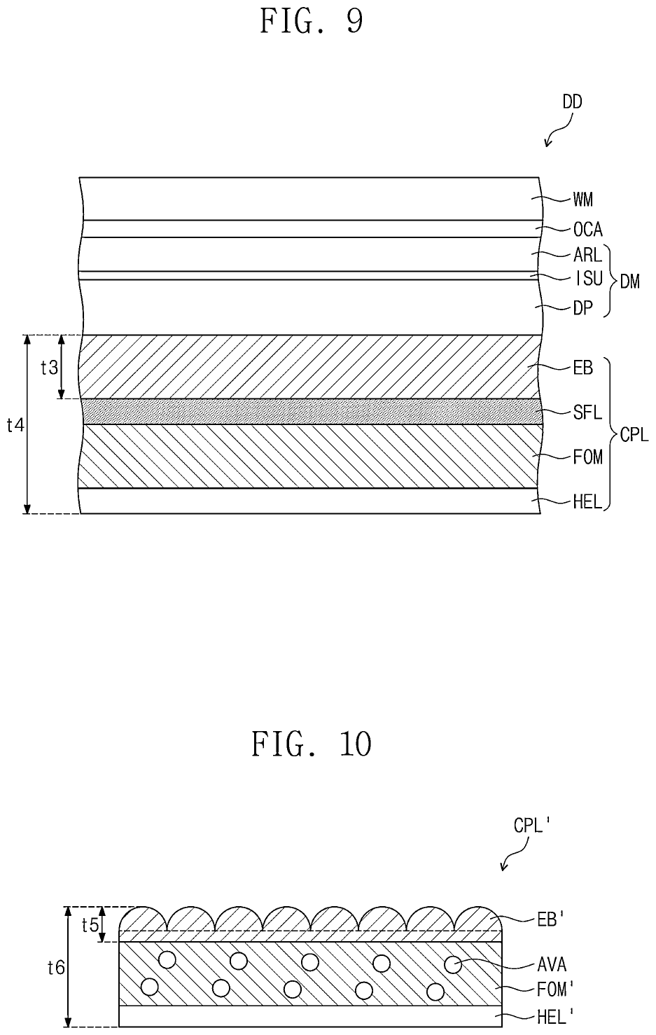

As an example, the lower adhesive layer EB may have a thickness t3 within a range from about 60 micrometers to about 80 micrometers. The thickness t3 of the lower adhesive layer EB may be defined as a third thickness t3. A thickness t4 of the lower support CPL may be defined as a fourth thickness t4. The third thickness t3 and the fourth thickness t4 will be described in detail with reference to FIG. 9.

The reinforcement film SFL may be disposed under the lower adhesive layer EB. The reinforcement film SFL may include carbon fiber reinforced plastics (CFRP) or stainless steel (e.g., SUS). The reinforcement film SFL may support the display panel DP (refer to FIG. 6) against the external force applied to the display device DD (refer to FIG. 1). The reinforcement film SFL may be omitted.

The cushion layer FOM may be disposed under the reinforcement film SFL. The cushion layer FOM may absorb external impact applied to the display device DD (refer to FIG. 1) from the outside of the display device DD (refer to FIG. 1) to protect the display panel DP (refer to FIG. 6).

The cushion layer FOM may include an impact-absorbing material such as a foam or sponge. The cushion layer FOM may include an acrylic-based polymer resin or a urethane-based polymer resin. As an example, the cushion layer FOM may have a thickness within a range from about 105 micrometers to about 155 micrometers.

The heat dissipation layer HEL may be disposed under the cushion layer FOM. The heat dissipation layer HEL disposed under the cushion layer FOM may perform a heat dissipation function. The heat dissipation layer HEL may include a thermally conductive material. The heat dissipation layer HEL may include stainless steel (SUS 304). The heat generated from components disposed under the display panel DP (refer to FIG. 6) may be dissipated through the heat dissipation layer HEL, and thus, the heat may be prevented from being transferred to the display panel DP (refer to FIG. 6).

The heat dissipation layer HEL may include electromagnetic shielding materials. Accordingly, electric and magnetic fields generated from electronic components placed below the heat dissipation layer HEL may be prevented from being transmitted to the display panel DP (refer to FIG. 6) placed on the lower support CPL.

Referring to FIG. 8B, the reinforcement film SFL (refer to FIG. 8A) may be omitted from the lower support CPLa. In this case, the lower adhesive layer EB may be disposed on the upper surface of the cushion layer FOM.

The lower support CPLa may further include a digitizer DGT. The digitizer DGT may be disposed between the cushion layer FOM and the heat dissipation layer HEL.

The digitizer DGT may receive information about locations indicated by a user on a display screen. The digitizer DGT may be implemented by an electromagnetic method or an electromagnetic resonance method. As an example, the digitizer DGT may include a digitizer sensor substrate including a plurality of coils, however, the present disclosure should not necessarily be limited thereto or thereby. According to an embodiment, the digitizer DGT may be implemented by an active electrostatic method.

When the user moves an electromagnetic pen on the display device DD, the electromagnetic pen may be driven by an alternating current signal to generate an oscillating magnetic field, and the oscillating magnetic field may induce a signal in the coils. The location of the electromagnetic pen may be detected based on the signal induced in the coils. The digitizer DGT may determine the location of the electromagnetic pen by detecting electromagnetic changes that occur when the electromagnetic pen approaches.

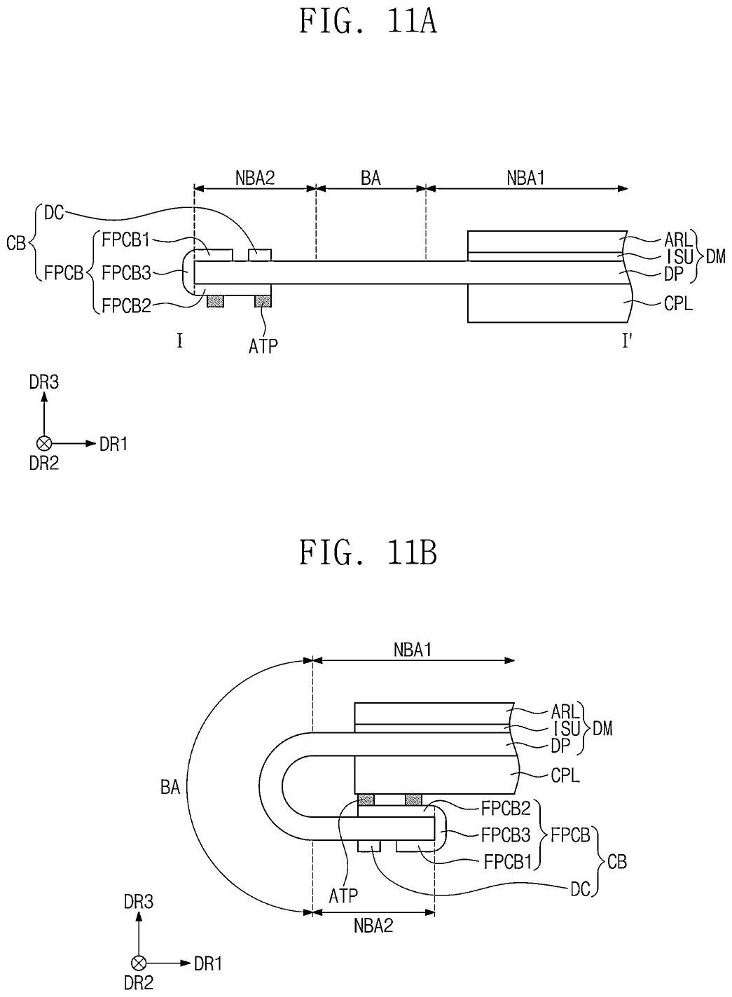

FIG. 9 is a cross-sectional view of a display device according to an embodiment of the present disclosure. FIG. 10 is a view of a lower support according to a comparative example.

As an example, the accommodation member (refer to FIG. 2) of the display device DD is omitted.

As an example, each of a display panel DP, an anti-reflective layer ARL, and a lower adhesive layer EB is schematically shown as a single layer.

A lower support CPL′, according to the comparative example, shown in FIG. 10 may be referred to as a first lower support CPL′, a lower adhesive layer EB′, according to the comparative example, shown in FIG. 10 may be referred to as a first lower adhesive layer EB′, a cushion layer FOM′, according to the comparative example shown in FIG. 10, may be referred to as a first cushion layer FOM′, and a heat dissipation layer HEL′, according to the comparative example shown in FIG. 10, may be referred as a first heat dissipation layer HEL′.

Since a window WM, an upper adhesive layer OCA, a display module DM, and a lower support CPL of FIG. 9 are substantially the same as the window WM of FIG. 2, the upper adhesive layer OCA and the display module DM of FIG. 6, and the lower support CPL of FIG. 8A, and to the extent that an element is not described in detail with respect to this figure, it may be understood that the element is at least similar to a corresponding element that has been described elsewhere within the present disclosure.

Referring to FIG. 9, the upper adhesive layer OCA may be disposed on the display module DM. The window WM may be disposed on the upper adhesive layer OCA. The display module DM may be coupled with the window WM by the upper adhesive layer OCA. The lower support CPL may be disposed under the display module DM. The lower support CPL disposed under the display module DM may support the display module DM.

Referring to FIG. 10, the first lower support CPL′ may include the first lower adhesive layer EB′, the first cushion layer FOM′, and the first heat dissipation layer HEL′. The first heat dissipation layer HEL′, the first cushion layer FOM′, and the first lower adhesive layer EB′ may be sequentially stacked.

The first lower adhesive layer EB′ may have a thickness t5 of about 30 micrometers. The first cushion layer FOM′ may be provided with pores AVA defined therein. The first heat dissipation layer HEL′ may include copper (Cu).

Referring to FIGS. 9 and 10, a fourth thickness t4 of the lower support CPL may be greater than a thickness t6 of the first lower support CPL′. For example, a third thickness t3 of the lower adhesive layer EB may be greater than the thickness t5 of the first lower adhesive layer EB′. In addition, as the lower support CPL includes the reinforcement film SFL, the fourth thickness t4 of the lower support CPL may be greater than the thickness t6 of the first lower support CPL′.

As the thickness of the lower support CPL increases, a resistance of the lower support CPL against the external force may increase even though the external force is applied to the display device DD. Accordingly, the deformation of the lower support CPL may be reduced, and therefore, the possibility that the deformation of the lower support CPL is visible to a user may be reduced.

In addition, in the case where the pores AVA are defined in the first cushion layer FOM′, the first cushion layer FOM′ in which the pores AVA are defined may be pressed and the pores AVA and the first cushion layer FOM′ may be distorted in shape when the external force is applied to the display device DD. Accordingly, the deformation of the first cushion layer FOM′ may be visible to a user.

However, the pores AVA might not be defined in the cushion layer FOM. Accordingly, the deformation of the cushion layer FOM may be reduced. Accordingly, a possibility that the deformation of the cushion layer FOM is visible to a user may be reduced.

In addition, as the lower support CPL includes the reinforcement film SFL, the reinforcement film SFL may absorb the external impact together with the cushion layer FOM when the external impact are applied to the display device DD. Therefore, the deformation of the lower support CPL may be reduced.

The heat dissipation layer HEL may include stainless steel. The first heat dissipation layer HEL′ may include copper. The stainless steel may have an elastic modulus greater than an elastic modulus of the copper. As the lower support CPL includes the heat dissipation layer HEL containing the stainless steel, a resistance of the lower support CPL against the external impact may increase. Accordingly, the deformation of the lower support CPL may be reduced, and the possibility that the deformation of the lower support CPL is visible to a user may be reduced.

FIGS. 11A and 11B are views illustrating the display module and the lower support shown in FIG. 2.

FIGS. 11A and 11B are cross-sectional views taken along a line I-I′ of FIG. 2.

For the convenience of explanation, the upper adhesive layer OCA and the window WM are omitted.

For the convenience of explanation, each of the display panel DP, the input sensor ISU, the anti-reflective layer ARL, and the lower support CPL is schematically shown as a single layer.

FIG. 11A shows a state in which the bending portion BA is not bent. FIG. 11B shows a state in which the bending portion BA is bent.

Since the driving chip DC, the input sensor ISU, the anti-reflective layer ARL, the display panel DP, and the lower support CPL of FIGS. 11A and 11B are substantially the same as the driving chip DC of FIG. 2 and the input sensor ISU, the anti-reflective layer ARL, the display panel DP, and the lower support CPL of FIG. 9, and thus, to the extent that an element is not described in detail with respect to this figure, it may be understood that the element is at least similar to a corresponding element that has been described elsewhere within the present disclosure.

Referring to FIGS. 2 and 11A, the display panel DP may include the first non-folding portion NBA1, the second non-folding portion NBA2, and the bending portion BA disposed between the first non-folding portion NBA1 and the second non-folding portion NBA2.

The display device DD may include the flexible circuit board FPCB and the driving chip DC. The flexible circuit board FPCB and the driving chip DC may be coupled with the second non-folding portion NBA2. The flexible circuit board FPCB and the driving chip DC may be disposed on the upper surface of the second non-folding portion NBA2. The flexible circuit board FPCB may be bent and connected to the second non-folding portion NBA2. The portion of the flexible circuit board FPCB, which is disposed on the upper surface of the second non-folding portion NBA2, may be defined as a first flexible circuit board FPCB1. The portion of the flexible circuit board FPCB, which is disposed on a lower surface of the second non-folding portion NBA2, may be defined as a second flexible circuit board FPCB2. The first flexible circuit board FCPB1 may be connected to the second flexible circuit board FPCB2, and a portion of the flexible circuit board FPCB, which is disposed at one side of the display panel DP, may be defined as a third flexible circuit board FPCB3.

The driving chip DC may include bump electrodes and integrated circuits, which are disposed on a surface facing the display panel DP. The display panel DP may include pad electrodes disposed on a surface facing the driving chip DC. The bump electrodes may be connected to the pad electrodes, and thus, the driving chip DC may be electrically connected to the display panel DP. The integrated circuits may be connected to the bump electrodes.

The flexible circuit board FPCB may include a timing controller. The timing controller may control an operation of the driving chip DC. The timing controller may generate a scan control signal and a data control signal in response to a control signal applied thereto from the outside.

The display device DD may further include an adhesive tape ATP. The adhesive tape ATP may be disposed on the flexible circuit board FPCB. The adhesive tape ATP may be disposed on a lower surface of the second flexible circuit board FPCB2 of the flexible circuit board FPCB. The lower surface of the second flexible circuit board FPCB2 may be defined as a surface facing an upper surface of the second flexible circuit board FPCB2 that is in contact with the second non-bending portion NBA2.

The adhesive tape ATP may be disposed at an edge of the second flexible circuit board FPCB2. FIG. 11A shows two adhesive tapes ATP as a representative example, however, the two adhesive tapes ATP may be provided integrally with each other. The adhesive tape ATP has a length within a range from about 3 mm to about 5 mm in the first direction DR1.

Referring to FIGS. 11A and 11B, the bending portion BA may be bent with respect to an axis extending in the second direction DR2. When the bending portion BA is bent, the second non-bending portion NBA2 may be disposed under the first non-bending portion NBA1. The driving chip DC and the flexible circuit board FPCB may be disposed under the first non-bending portion NBA1.

The flexible circuit board FPCB may be disposed under the lower support CPL. The lower surface of the second flexible circuit board FPCB2 may face a lower surface of the lower support CPL. The adhesive tape ATP may be disposed between the lower surface of the second flexible circuit board FPCB2 and the lower surface of the lower support CPL. The flexible circuit board FPCB may be coupled with the lower support CPL by the adhesive tape ATP, and the bending portion BA may be maintained in the bent state.

According to an embodiment, the adhesive tape ATP may be provided to entirely cover the lower surface of the second flexible circuit board FPCB2 to fix the flexible circuit board FPCB to the lower surface of the lower support CPL. In this case, the adhesive tape ATP may be deformed corresponding to the flexible circuit board FPCB, and the shape of the flexible circuit board FPCB may be visible to a user.

In addition, in the case where the adhesive tape ATP entirely covers the lower surface of the flexible circuit board FPCB, components such as the timing controller disposed on the lower surface of the flexible circuit board FPCB may be covered by the adhesive tape ATP. The adhesive tape ATP may be deformed corresponding to the shape of the flexible circuit board FPCB and may be visible to a user.

However, according to the present disclosure, the adhesive tape ATP may be disposed only at the edge of the second flexible circuit board FPCB2. As the adhesive tape ATP is disposed at the edge of the second flexible circuit board FPCB2, a size of the flexible circuit board FPCB visible to a user may be reduced. In addition, as the adhesive tape ATP does not cover the flexible circuit board FPCB, the shape of the flexible circuit board FPCB might not be viewed.

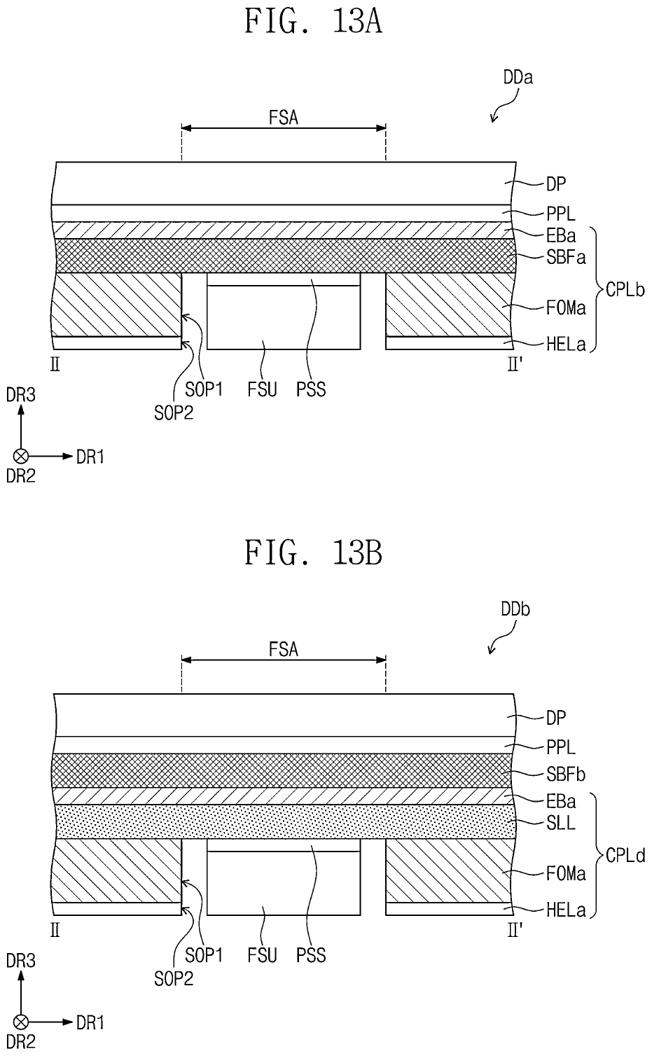

FIG. 12 is a perspective view of a display device DDa according to an embodiment of the present disclosure.

Since the display device Dda shown in FIG. 12 is substantially the same as the display device DD shown in FIG. 1, descriptions about the display device Dda of FIG. 12 will be focused on different features from those of the display device DD of FIG. 1 and to the extent that an element is not described in detail with respect to this figure, it may be understood that the element is at least similar to a corresponding element that has been described elsewhere within the present disclosure.

Referring to FIG. 12, a sensor area FSA may be defined in a display surface DD-ISa. The sensor area FSA may overlap a display area DD-DA and may be used to sense a fingerprint.

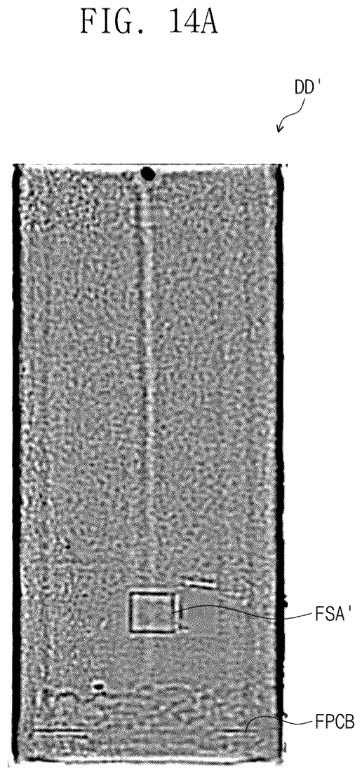

FIGS. 13A and 13B are views illustrating display devices DDa and DDb according to embodiments of the present disclosure.

FIGS. 13A and 13B are cross-sectional views taken along a line II-II′ shown in FIG. 12.

In FIGS. 13A and 13B, the anti-reflective layer ARL (refer to FIG. 5), the window WM (refer to FIG. 2), and the input sensor ISU (refer to FIG. 2) are omitted.

Since a display panel DP and a panel protective layer PPL shown in FIGS. 13A and 13B are substantially the same as the display panel DP and the panel protective layer PPL shown in FIG. 6, details thereof will be omitted.

In addition, descriptions about the display device DDb shown in FIG. 13B will be focused on different features from those of the display device DDa shown in FIG. 13A and to the extent that an element is not described in detail with respect to this figure, it may be understood that the element is at least similar to a corresponding element that has been described elsewhere within the present disclosure.

Referring to FIG. 13A, the panel protective layer PPL may be disposed under the display panel DP. A lower support CPLc and a sensor unit FSU may be disposed under the panel protective layer PPL.

The lower support CPLc may include a lower adhesive layer EBa, a light blocking layer SBFa, a cushion layer FOMa, and a heat dissipation layer HELa.

The lower adhesive layer EBa may be disposed on a lower surface of the panel protective layer PPL. The lower adhesive layer EBa may include the protruding patterns PP (refer to FIG. 8A). As an example, the lower adhesive layer EBa may have a thickness within a range from about 20 micrometers to about 40 micrometers.

The light blocking layer SBFa may be disposed under the lower adhesive layer EBa. The light blocking layer SBFa may reduce a reflectance of an external light. As an example, the light blocking layer SBFa may be a polarization film including a retarder and/or a polarizer.

However, this is merely an example, and the light blocking layer SBFa may include a black coloring agent. In this case, the black coloring agent may include a black pigment or a black dye. The black coloring agent may include a metal, such as carbon black, chromium, or an oxide thereof.

The cushion layer FOMa may be disposed under the light blocking layer SBFa. The cushion layer FOMa may be disposed on a lower surface of the light blocking layer SBFa. In FIG. 13A, the cushion layer FOMa is provided in plural, however, the cushion layers may be provided integrally with each other.

The cushion layer FOMa might not overlap a sensor area FSA. The cushion layer FOMa may be disposed in the sensor area FSA. A first sensor opening SOP1 may be defined by the cushion layer FOMa.

The heat dissipation layer HELa may be disposed under the cushion layer FOMa. The heat dissipation layer HELa may be disposed on a lower surface of the cushion layer FOMa. In FIG. 13A, the heat dissipation layer HELa is provided in plural, however, the heat dissipation layers HELa may be provided integrally with each other. The heat dissipation layer HELa may include stainless steel (e.g., SUS).

The heat dissipation layer HELa might not overlap the sensor area FSA. The heat dissipation layer HELa might not be disposed in the sensor area FSA. A second sensor opening SOP2 may be defined by the heat dissipation layer HELa. The first sensor opening SOP1 may be defined integrally with the second sensor opening SOP2.

A sensor adhesive layer PSS may be disposed in the first sensor opening SOP1. The sensor adhesive layer PSS may be disposed on the lower surface of the light blocking layer SBFa. As an example, a length in the first direction DR1 of the sensor adhesive layer PSS may be smaller than a length in the first direction DR1 of the first sensor opening SOP1. The sensor adhesive layer PSS may include a pressure sensitive adhesive (PSA).

The sensor unit FSU may be disposed in the first sensor opening SOP1 and the second sensor opening SOP2. The sensor unit FSU may be disposed under the sensor adhesive layer PSS. The sensor unit FSU may be disposed on a lower surface of the sensor adhesive layer PSS. The sensor unit FSU may be attached to the light blocking layer SBFa by the sensor adhesive layer PSS.

The sensor unit FSU may be provided as a fingerprint recognition sensor and may operate in an optical, ultrasonic, or capacitive method. The fingerprint recognition sensor is described as the sensor unit FSU as a representative example; however, the present disclosure should not necessarily be limited thereto or thereby. Various sensors, such as a proximity sensor, a pressure sensor, a brightness sensor, and a temperature sensor, may be provided as the sensor unit FSU.

When the sensor unit FSU is attached to the sensor adhesive layer PSS, a pressure may be applied to the sensor unit FSU. Accordingly, the sensor adhesive layer PSS may be deformed. The deformation of the sensor adhesive layer PSS may be visible to a user when the external light is reflected.

However, according to the display device DDa of the present disclosure, the light blocking layer SBFa may be disposed on the sensor adhesive layer PSS. Therefore, the light blocking layer SBFa may prevent the external light from being reflected. Thus, a possibility that the deformation of the sensor adhesive layer PSS is visible to a user may be reduced.

Referring to FIG. 13B, the display device DDb may include the display panel DP, the panel protective layer PPL, a light blocking layer SBFb, and a lower support CPLd. The light blocking layer SBFb may be disposed on a lower surface of the panel protective layer PPL. The light blocking layer SBFb may be disposed between the panel protective layer PPL and a lower adhesive layer EBa.

The light blocking layer SBFb may reduce a reflectance of an external light. As an example, the light blocking layer SBFb may be a polarization film including a retarder and/or a polarizer.

However, this is merely an example, and the light blocking layer SBFb may include a black coloring agent. In this case, the black coloring agent may include a black pigment or a black dye. The black coloring agent may include a metal, such as carbon black, chromium, or an oxide thereof.

The lower support CPLd may be disposed under the light blocking layer SBFb. The lower support CPLd may be disposed on a lower surface of the light blocking layer SBFb. The lower support CPLd may include the lower adhesive layer EBa, a reinforcement layer SLL, a cushion layer FOMa, and a heat dissipation layer HELa. For example, different from the lower support CPLc shown in FIG. 13A, the lower support CPLd shown in FIG. 13B might not include the light blocking layer SBFb.

The lower adhesive layer EBa may be disposed on the lower surface of the light blocking layer SBFb. The reinforcement layer SLL may be disposed under the lower adhesive layer EBa. As an example, the reinforcement layer SLL may include polyethylene naphthalate (PEN) or polyimide (PI).

The cushion layer FOMa may be disposed on a lower surface of the reinforcement layer SLL. The cushion layer FOMa might not overlap a sensor area FSA. The cushion layer FOMa might not be disposed in the sensor area FSA. A first sensor opening SOP1 may be defined by the cushion layer FOMa.

The heat dissipation layer HELa may be disposed on a lower surface of the cushion layer FOMa. The heat dissipation layer HELa may include stainless steel (e.g., SUS). The heat dissipation layer HELa might not overlap the sensor area FSA. The heat dissipation layer HELa may be disposed in the sensor area FSA. A second sensor opening SOP2 may be defined by the heat dissipation layer HELa.

A sensor adhesive layer PSS and a sensor unit FSU may be disposed in the first sensor opening SOP1 and the second sensor opening SOP2. The sensor unit FSU may be attached to the lower surface of the reinforcement layer SLL by the sensor adhesive layer PSS.

The reflection of the external light may be prevented by the light blocking layer SBFb disposed on the lower surface of the panel protective layer PPL. Accordingly, the light blocking layer SBFb may prevent the sensor unit FSU and the sensor adhesive layer PSS from being viewed due to the external light.

In addition, as the lower support CPLd includes the reinforcement layer SLL, the lower adhesive layer EBa disposed on an upper surface of the reinforcement layer SLL might not be recessed. Therefore, the recess of the lower adhesive layer EBa may be prevented from being visible to a user.

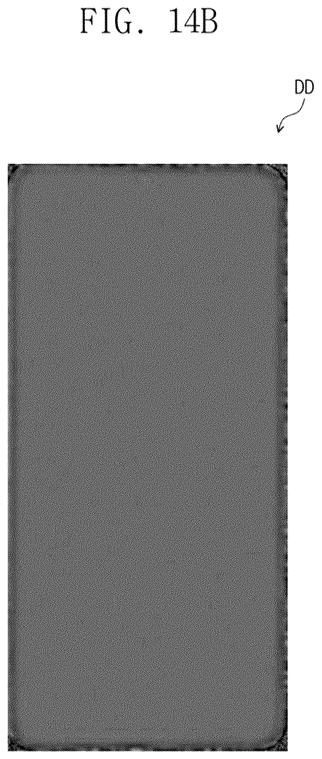

FIGS. 14A and 14B are views illustrating display devices according to a comparative example and an embodiment example of the present disclosure.

FIG. 14A shows the display device DD′ according to the comparative example, and FIG. 14B shows the display device DD according to the embodiment example of the present disclosure.

FIGS. 14A and 14B are plan views of the display device DD′ and the display device DD.

Referring to FIGS. 7, 10, and 14A, the upper adhesive layer OCA′ of the display device DD′ according to the comparative example has the thickness within the range from about 140 micrometers to about 160 micrometers, and the elastic modulus of the upper adhesive layer OCA′ is about 0.23 megapascals. In addition, the pores are defined in the cushion layer FOM′ of the lower support CPL′.

Referring to FIGS. 9, 11B, 13A, and 14B, the display device DD, according to the present disclosure, may include the upper adhesive layer OCA and the lower support CPL and CPLb. The upper adhesive layer OCA may have the thickness within the range from about 75 micrometers to about 100 micrometers, and the elastic modulus of the upper adhesive layer OCA may be within the range from about 0.36 megapascals to about 0.44 megapascals. The pores might not be defined in the cushion layer FOM of the lower support CPL and CPLb (i.e., the cushion layer FOM might be non-porous). In addition, the adhesive tape ATP may be disposed only at the edge of the flexible circuit board FPCB. In the case where the display device DD includes the sensor unit FSU, the sensor unit FSU may overlap the light blocking layer SBFa.

Referring to FIGS. 14A and 14B, the flexible circuit board FPCB (refer to FIG. 2) and the sensor unit FSU (refer to FIG. 13A), which are disposed on the lower surface of the display device DD′, may be visible to a user. However, the flexible circuit board FPCB (refer to FIG. 2) and the sensor unit FSU (refer to FIG. 13A) of the display device DDa might not be visible to a user.

TABLE 1

| | DD′ | | DD | |
|---|---|---|---|---|
| | PMD | Visual | PMD | Visual |
| | measurement | inspection | measurement | inspection |
| Defective surface | 0.7 | Viewed | 0.56 | Not viewed |
| viewed | | | | |
| flexible circuit | 2.23 | Viewed | 0.72 | Not viewed |
| board (FPCB) | | | | |
| shape viewed | | | | |
| sensor unit | 4.91 | Viewed | 0.68 | Not viewed |
| FSU shape | | | | |
| viewed | | | | |

Table 1 shows results of testing whether the defective surface, the shape of the flexible circuit board FPCB, and the shape of the sensor unit FSU of each of the display devices DD′ and DD are visible from the outside. The test may be performed through the visual inspection and the phase measuring deflectometry (PMD) measurement. The PMD measurement is a method of inspecting a distortion of the surface of the display devices DD′ and DD by analyzing a phase shift pattern of a light incident into a camera using an external sensor when the light is reflected on the surface of the display devices DD′ and DD and enters the camera. As a value of the PMD measurement decreases, defects, such as the defective surface, are less likely to be observed.

Referring to Table 1, in the case of the display device DD′ according to the comparative example, the defective surface, the shape of the flexible circuit board FPCB (refer to FIG. 2), and the shape of the sensor unit FSU (refer to FIG. 13A) are visible to the naked eye. However, in the case of the display device DD, the defective surface, the shape of the flexible circuit board FPCB (refer to FIG. 2), and the shape of the sensor unit FSU (refer to FIG. 13A) are not visible.

In addition, according to the results obtained through the PMD test, the PMD value of the display device DD, according to the present disclosure, is lower than that of the display device DD′, according to the comparative example, within the same test item.

Although the embodiments of the present disclosure have been described, it is understood that the present disclosure should not necessarily be limited to these embodiments but various changes and modifications can be made by one ordinary skilled in the art within the spirit and scope of the present disclosure. Therefore, the disclosed subject matter should not necessarily be limited to any single embodiment described herein.

What is claimed is:

1. A display device, comprising:
a display panel comprising a first non-bending portion, a bending portion, and a second non-bending portion;
a flexible circuit board comprising a first flexible circuit board disposed on an upper surface of the second non-bending portion and a second flexible circuit board disposed on a lower surface of the second non-bending portion;
a lower support disposed under the first non-bending portion; and
an adhesive tape disposed on a lower surface of the lower support and a lower surface of the second flexible circuit, wherein the adhesive tape disposed on the lower surface of the second flexible circuit board is disposed at an edge of the second flexible circuit board.

2. The display device of claim 1, wherein the lower support comprises:
a lower adhesive layer;
a cushion layer disposed under the lower adhesive layer; and
a heat dissipation layer disposed under the cushion layer.

3. The display device of claim 2, wherein the lower adhesive layer has a thickness within a range from about 60 micrometers to about 80 micrometers.

4. The display device of claim 2, wherein the cushion layer is nonporous.

5. The display device of claim 4, wherein the cushion layer has a thickness within a range from about 105 micrometers to about 155 micrometers.

6. The display device of claim 2, wherein the heat dissipation layer comprises stainless steel.

7. The display device of claim 2, wherein the lower support further comprises a reinforcement film disposed between the lower adhesive layer and the cushion layer, and the reinforcement film comprises stainless steel or a carbon fiber reinforced plastic.

8. The display device of claim 2, wherein the lower support further comprises a digitizer disposed between the cushion layer and the heat dissipation layer.

9. The display device of claim 2, wherein the display panel comprises a sensor area defined in a front surface thereof, a first sensor opening is defined in an area of the sensor area that overlaps the cushion layer, and a second sensor opening is defined in an area of the sensor area that overlaps the heat dissipation layer.

10. The display device of claim 9, wherein the lower support further comprises a light blocking layer disposed between the cushion layer and the lower adhesive layer.

11. The display device of claim 10, further comprising a sensor unit disposed in the first sensor opening and the second sensor opening and attached to a lower surface of the light blocking layer, which is exposed through the first and second sensor openings without being covered by the cushion layer.

12. The display device of claim 9, further comprising a light blocking layer disposed between the display panel and the lower support, wherein the lower support further comprises a reinforcement layer disposed between the lower adhesive layer and the cushion layer.

13. The display device of claim 1, further comprising:
an anti-reflective layer disposed on the display panel and comprising color filters or a light control layer; and
an upper adhesive layer disposed on the anti-reflective layer, the upper adhesive layer being optically transparent.

14. The display device of claim 13, wherein the upper adhesive layer has a thickness within a range from about 75 micrometers to about 100 micrometers.

15. The display device of claim 14, wherein the upper adhesive layer has an elastic modulus within a range from about 0.36 megapascals to about 0.44 megapascals.

16. A display device, comprising:
a display panel comprising a first non-bending portion, a bending portion, and a second non-bending portion; and
a lower support disposed under the display panel, the lower support comprising:
a lower adhesive layer comprising a plurality of protruding patterns disposed on a surface thereof facing the display panel;
a cushion layer disposed under the lower adhesive layer; and
a heat dissipation layer disposed under the cushion layer and comprising stainless steel, wherein the cushion layer is non porous.

17. The display device of claim 16, wherein the lower support further comprises a reinforcement film disposed between the lower adhesive layer and the cushion layer, and the reinforcement film comprises stainless steel or a carbon fiber reinforced plastic.

18. The display device of claim 16, wherein the lower adhesive layer has a thickness within a range from about 250 micrometers to about 300 micrometers, and the cushion layer has a thickness within a range from about 105 micrometers to about 155 micrometers.

19. The display device of claim 16, further comprising:
an anti-reflective layer disposed on the display panel and comprising color filters or a light control layer; and
an upper adhesive layer disposed on the anti-reflective layer and being optically transparent, wherein the upper adhesive layer has a thickness within a range from about 75 micrometers to about 100 micrometers.

20. The display device of claim 16, further comprising:
a flexible circuit board comprising a first flexible circuit board disposed on an upper surface of the second non-bending portion and a second flexible circuit board disposed on a lower surface of the second non-bending portion; and
an adhesive tape attached to a lower surface of the second flexible circuit board, wherein the adhesive tape is disposed between a lower surface of the lower support and the lower surface of the second flexible circuit board and the flexible circuit board is disposed under the lower support, and the adhesive tape is disposed exclusively at an edge of the second flexible circuit board.
